(19) United States
(12) Patent Application Publication
(10) Pub. No.: US 2013/0341701 A1
(43) Pub. Date: Dec. 26, 2013

(54) Vertical Semiconductor Memory Device and Manufacturing Method Thereof

(71) Applicants: Pieter Blomme, Heverlee (BE); Gouri Sankar Kar, Heverlee (BE)

(72) Inventors: Pieter Blomme, Heverlee (BE); Gouri Sankar Kar, Heverlee (BE)

(73) Assignee: IMEC, Leuven (BE)

(21) Appl. No.: 13/877,616

(22) PCT Filed: Oct. 6, 2011
(86) PCT No.: PCT/EP2011/067459

§ 371 Date: Sep. 12, 2013

Related U.S. Application Data
(60) Provisional application No. 61/394,246, filed on Oct. 18, 2010.

(51) Int. Cl. H01L 29/792; H01L 29/66

(52) U.S. Cl. CPC H01L 29/792; H01L 29/66833
USPC 257/324; 438/591

(57) ABSTRACT

Disclosed are vertical semiconductor devices and methods of manufacturing vertical semiconductor devices. An example method includes providing a semiconductor substrate, and forming a stack of horizontal layers on the semiconductor substrate, where the horizontal layers are substantially parallel to a surface of the semiconductor substrate, and the horizontal layers comprise alternating conductive layers and dielectric layers. The method further includes forming a vertical channel region through the stack of horizontal layers, where the vertical channel region is substantially perpendicular to a surface of the semiconductor substrate, and the vertical channel region comprises sidewall surfaces. The method further includes forming a charge storage layer on regions of the sidewall surfaces of the vertical channel region that are in direct contact with conductive layers in the stack of horizontal layers and, at a distance from the vertical channel region, forming a vertical dielectric region through the stack of horizontal layers.

### FIELD OF THE INVENTION

The present invention relates to a vertical semiconductor device and is more particularly, although not exclusively concerned with a three dimensional stacked semiconductor memory device and the method for making thereof.

### BACKGROUND TO THE INVENTION

There is a continuous need for increasing bit density and reducing bit cost in memory devices, and new alternatives are being proposed for ultra-high density memory technologies, such as, three-dimensional (3D) stacked memories. One possible solution for multi-stacked memories is to use Bit Cost Scalable (BiCS) technology as described by Tanaka et al. in “Bit Cost Scalable Technology with Punch and Plug Process for Ultra High Density Flash Memory”, VLSI Technology Symposium 2007. In BiCS technology a multi-stacked memory array is formed by so-called punch and plug. A whole stack of electrode plates is punched through and plugged by another electrode material.

If a charge storage layer is provided in the punched hole before being plugged by another electrode material, stored charge tends to diffuse along the charge storage layer and to move away from a region where it can be sensed. In addition, the stored charge can diffuse towards a neighbouring region and interfere with the charge at the neighbouring region. Such interference prevents reliable reading out of the charge present in the neighbouring region as well as in the region from which the charge diffused.

Whilst this effect can be reduced by increasing the spacing between the regions where charge is stored in the device, this disadvantageously provides limits in size and separation in the vertical direction for different regions of the device.

### SUMMARY OF THE INVENTION

It is therefore an object of the present invention to provide a vertical semiconductor device which has substantially reduced charge leakage.

It is another object of the present invention to provide an improved vertical non-volatile memory device and a method of manufacturing such a device.

It is a further object of the present invention to provide a vertical semiconductor device with improved performance and method for manufacturing such a vertical semiconductor device.

It is yet a further object of the present invention to provide a vertical semiconductor memory device with improved density and a method for manufacturing such a vertical semiconductor memory device.

In accordance with a first aspect of the present invention, there is provided a vertical semiconductor device comprising a semiconductor substrate; a stack of horizontal layers formed on the semiconductor substrate, the stack comprising alternating horizontal dielectric layers and horizontal conductive gate layers; each horizontal conductive gate layer being positioned between, and in direct contact with, two horizontal dielectric layers; a vertical channel semiconductor region extending through the stack of horizontal layers; and a charge storage layer; characterised in that the charge storage layer is discontinuous and in that the charge storage layer is only present at at least one interface between the vertical channel semiconductor region and each horizontal conductive gate layers.

By having discrete charge regions in the charge storage layer, stored charge cannot move away from the region where it is to be sensed.

In addition, each memory cell in the vertical semiconductor device and their spacing can be made smaller in the vertical direction, that is, a direction orthogonal to the substrate and the layers formed thereon.

In this way, a vertical memory device may be provided with good performance and high density.

In one embodiment, the vertical semiconductor device further comprises a vertical dielectric region parallel to and spaced at a predetermined distance D from the vertical channel region. Preferably, each horizontal dielectric layer is in contact with both the vertical channel semiconductor region and the vertical dielectric region.

In a preferred embodiment, the vertical dielectric region and each horizontal dielectric layer comprise the same dielectric material.

Advantageously, the charge storage layer comprises a charge trapping layer.

In another embodiment, the charge storage layer further comprises additional dielectric layers. In this embodiment, the charge storage layer may comprise a stack of layers comprising at least a charge tunnelling layer, a charge trapping layer and a charge blocking layer. It is preferred that the horizontal dielectric layers are in electrical contact with the vertical channel region via the charge tunnelling layer in between the horizontal dielectric layer and the vertical channel region.

The vertical dielectric region may comprise air-gap insulation. In accordance with another aspect of the present invention, there is provided a method for manufacturing a vertical semiconductor device comprising the steps of:

a) providing a semiconductor substrate;

b) forming a stack of horizontal layers on the semiconductor substrate, the stack comprising alternating conductive and dielectric layers;

c) forming a vertical channel through the stack of layers, the vertical channel comprising a sidewall surface and a bottom surface;

d) forming a charge storage layer at the sidewall surfaces of the vertical channel;

characterised in that step d) comprises forming the charge storage layer only on regions of the sidewall surface where the charge storage layer is in direct contact with the horizontal conductive layers of the stack of layers.

It is an advantage of the method of the present invention that a cost-effective integration flow may be applied for manufacturing a vertical semiconductor memory device.

In one embodiment, step d) may comprise the step of removing part of the alternating horizontal conductive layers and dielectric layers before forming the charge storage layer.

Additionally, step d) may comprise removing parts of the charge storage layer which are in direct contact with the horizontal dielectric layers of the stack of layers. In this case, the step of removing parts of the charge storage layer may comprise altering the charge storage layer.

In another embodiment where the charge storage layer comprises a conductive layer, the step of altering the charge storage layer may comprise oxidising the conductive layer to form a dielectric layer.

In a further embodiment, step d) comprises forming a stack of layers comprising at least a charge tunneling layer, a charge trapping layer and a charge blocking layer at the sidewall surfaces of the vertical channel.

Ideally, step d) comprises forming a vertical dielectric region through the stack of layers at a distance D from the vertical channel.

Additionally, the step of forming a vertical dielectric region may comprise the steps of: forming an opening through the stack of layers, the opening being at the distance D from the vertical channel; removing the exposed horizontal dielectric layers to expose parts of the charge storage layer; and filling the opening with a dielectric layer.

As a final step, preferably, step d) further comprises filling the vertical channel with a semiconductor material after formation of the charge storage layer.

In another embodiment of the present invention, a method for reading and/or writing a vertical semiconductor device may be provided.

### BRIEF DESCRIPTION OF THE DRAWINGS

For a better understanding of the present invention, reference will now be made, by way of example only, to the accompanying drawings in which:

FIGS. 1 to 11 illustrate sectioned views corresponding to manufacturing steps utilised for forming a vertical semiconductor device in accordance with the present invention; and

FIG. 12 illustrates a flow chart of the steps for forming the vertical semiconductor device in accordance with the present invention.

### DESCRIPTION OF THE INVENTION

The present invention will be described with respect to particular embodiments and with reference to certain drawings but the invention is not limited thereto. The drawings described are only schematic and are non-limiting. In the drawings, the size of some of the elements may be exaggerated and not drawn on scale for illustrative purposes.

It will be understood that the terms “vertical” and “horizontal” are used herein refer to particular orientations of the Figures and these terms are not limitations to the specific embodiments described herein.

The terms “first”, “second” and the like in the description are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms “top”, “bottom”, “over”, “under” and the like in the description are used for descriptive purposes and not necessarily for describing relative positions. The terms so used are interchangeable under appropriate circumstances and the embodiments of the invention described herein can operate in other orientations than described or illustrated herein. For example, “underneath” and “above” an element indicates being located at opposite sides of this element.

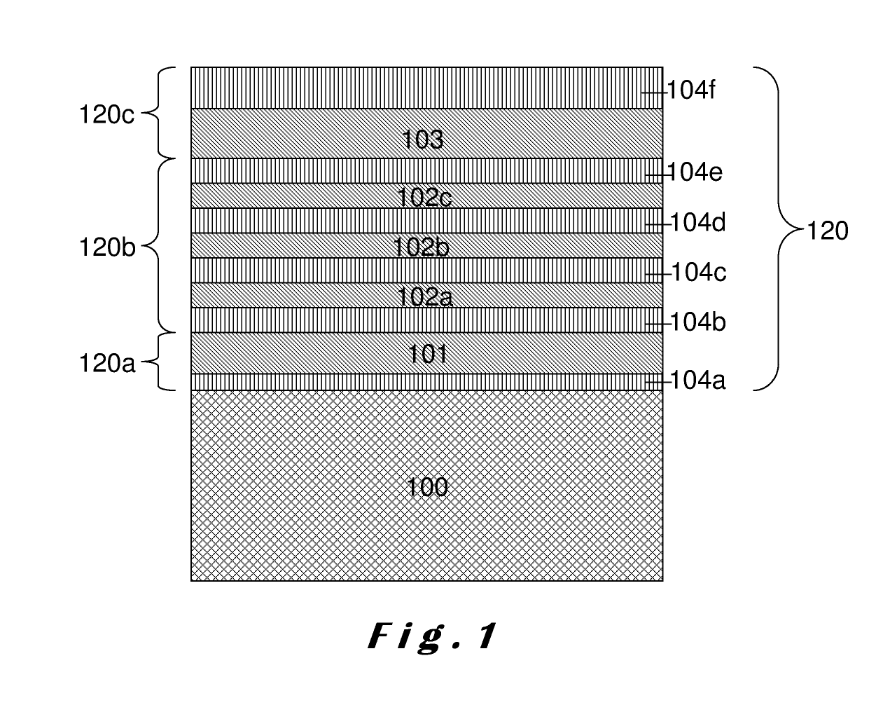

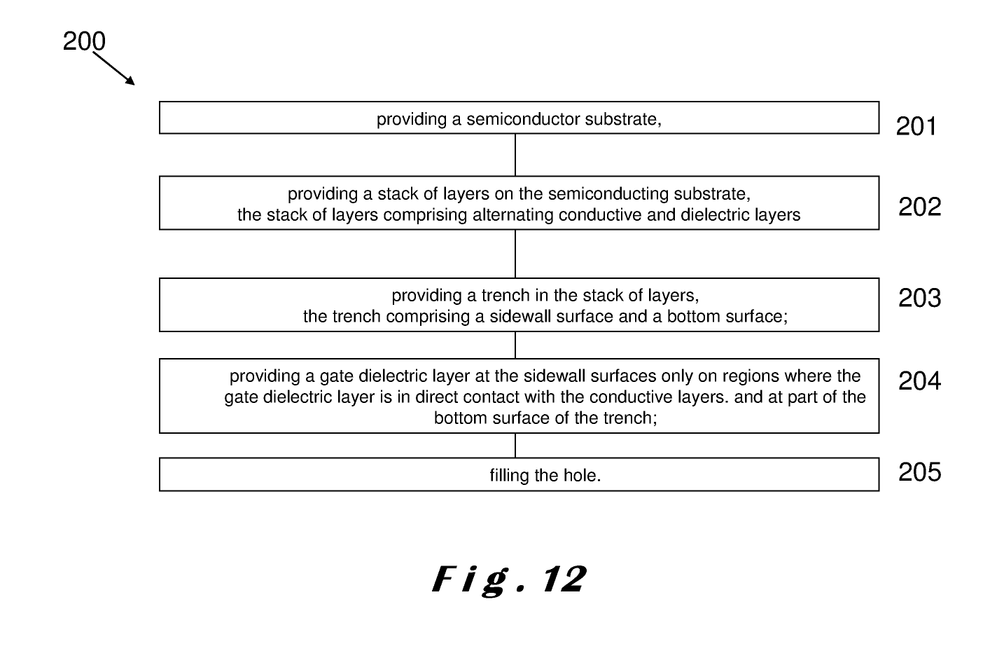

A method for manufacturing a vertical semiconductor device in accordance with the present invention will be described with reference to the flow chart of FIG. 12 while referring to FIGS. 1 to 11 which illustrate the various steps in more detail.

A flow chart 200 illustrating the manufacturing steps for a vertical semiconductor device in accordance with the present invention is shown in FIG. 12. The first step, step 201, comprises providing a semiconductor substrate 100 (FIG. 1) on which a stack 120 of layers 101, 102a, 102b, 102c, 103, 104a, 104b, 104c, 104d, 104e, 104f is formed. The semiconductor substrate 100 comprises a semiconducting material, for example, a silicon substrate.

The semiconducting material may be monocrystalline or single crystalline. By the term “monocrystalline” or single crystalline material is meant a material in which a sample has a crystal lattice which is continuous and the crystal lattice iss unbroken up to the edges of the sample, with no grain boundaries.

The semiconducting material may be polycrystalline. By the term “polycrystalline” material is meant a material comprising a plurality of small material crystals, for example, polycrystalline silicon is a material comprising a plurality of small silicon crystals.

The semiconducting material may be amorphous. By the term “amorphous” is meant the non-crystalline allotropic form of the material. For example, silicon may be amorphous (a-Si), monocrystalline (c-Si) or polycrystalline (poly-Si).

The semiconducting material is preferably monocrystalline or single crystalline, such as, for example, monocrystalline Si.

A stack 120 of layers 101, 102a, 102b, 102c, 103, 104a, 104b, 104c, 104d, 104e, 104f is provided on the semiconductor substrate 100 as shown in FIG. 1, step 202. The stack 120 of layers 101, 102a, 102b, 102c, 103, 104a, 104b, 104c, 104d, 104e, 104f comprises alternating conductive layers 101, 102a, 102b, 102c, 103 and dielectric layers 104a, 104b, 104c, 104d, 104e, 104f. The stack 120 of layers 101, 102a, 102b, 102c, 103, 104a, 104b, 104c, 104d, 104e, 104f may be divided into at least a lower stack 120a of layers, a middle stack 120b of layers and an upper stack 120c of layers. The lower stack 120a of layers 120a comprises a lower conductive layer 101 formed on a dielectric layer 104a on the semiconducting substrate 100. The middle stack 120b of layers comprises at least one middle conductive layer 102a, 102b, 102c formed on at least one middle dielectric layer 104b, 104c, 104d as shown, the lowest middle dielectric layer 104b being formed on the lower stack 120a of layers. The upper stack 120c of layers comprises an upper dielectric layer 104f formed on an upper conductive layer 103, the upper conductive layer 103 being formed on the middle stack 120b of layers.

The stack 120 of layers 101, 102a, 102b, 102c, 103, 104a, 104b, 104c, 104d, 104e, 104f is provided in a first direction, more particularly, in a horizontal direction. This means the layers 101, 102a, 102b, 102c, 103, 104a, 104b, 104c, 104d, 104e, 104f are provided in the same direction as upper surface of the semiconductor substrate 100.

In order to manufacture a three-dimensional memory device, a vertical transistor with at least one associated channel is necessary. For this, a stack of gate plates is provided, the gate plates corresponding to the conductive layers 101, 102a, 102b, 102c, 103. Each gate plate acts as a control gate except the lowest gate plate, corresponding to the lowermost conductive layer 101, which takes a role of a lower select gate, and the highest gate plate, corresponding to the uppermost conductive layer 103, which takes a role of upper select gate. Alternatively, for example, in case of a pipe-BiCS semiconductor device, the highest gate plate may act as both the lower and upper select gates. In between the lower and upper select gates, a number of control gates are provided which correspond to middle conductive layers 102a, 102b, 102c. The number of control gate plates, corresponding to the number of middle conductive layers 102a, 102b, 102c, determines the bit density of the final memory device. By adding more middle conductive layers or control gates, the bit density may be increased without adding more complexity to the process flow of the memory device.

In its simplest form, the stack of layers may only comprise three conductive layers, where the lowermost conductive layer forms a lower select gate, the uppermost conductive layer forms an upper select gate, and a middle conductive layer which forms a control gate. However for improved bit density, more than one middle conductive layer needs to be formed together with associated middle dielectric layers. For a higher density of the memory device, the middle stack of layers preferably comprises between about 8 up to 64, or even more, middle conductive layers separated from one another by middle dielectric layers.

The stack 120 of layers 101, 102a, 102b, 102c, 103, 104a, 104b, 104c, 104d, 104e, 104f may be formed using standard deposition techniques known to a person skilled in the art, such as, for example, chemical vapour phase deposition (CVD), more preferably, low pressure CVD (LPCVD).

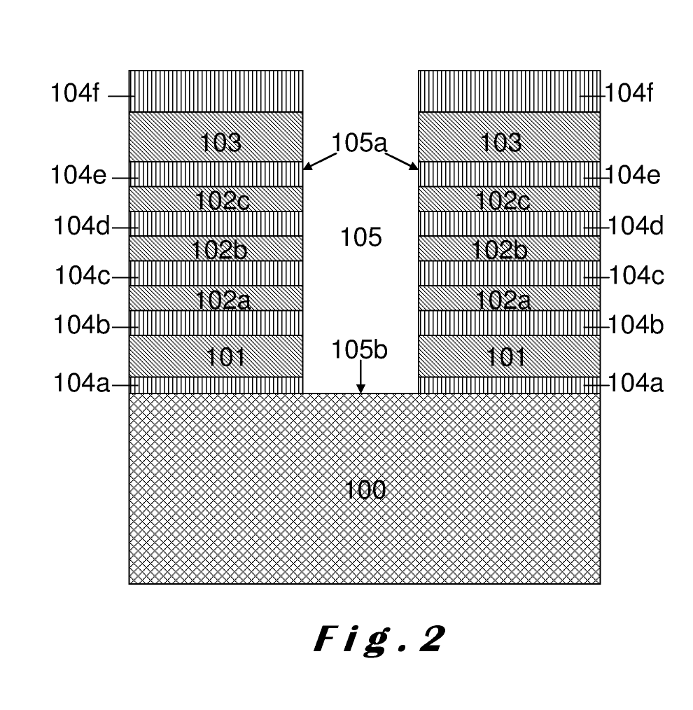

In a next step, step 203 as shown in FIG. 2, at least one hole or trench 105 is provided in the stack 120 of layers 101, 102a, 102b, 102c, 103, 104a, 104b, 104c, 104d, 104e, 104f, the hole 105 comprising a sidewall surface 105a and a bottom surface 105b. According to a preferred embodiment, each hole 105 may be provided thereby exposing part of the underlying semiconductor substrate 100. However, alternatively, for example, in case of a pipe-BiCS semiconductor device, at least two holes 105 are provided through the stack 120 of layers 101, 102a, 102b, 102c, 103, 104a, 104b, 104c, 104d, 104e, 104f, the holes 105 being connected to one another on the semiconductor substrate 100.

In the hole 105, a vertical channel region of the vertical semiconductor or memory device will be formed. By the term “vertical” is meant according to a second direction, the second direction being substantially orthogonal the first direction of the stack 120 of layers 101, 102a, 102b, 102c, 103, 104a, 104b, 104c, 104d, 104e, 104f. Holes for the transistor channel are thus punched through the stack 120 of layers 101, 102a, 102b, 102c, 103, 104a, 104b, 104c, 104d, 104e, 104f. The formation of each hole 105 may be achieved using standard process techniques known to a person skilled in the art, such as, for example, a lithography step comprising forming a hard mask layer on the stack 120 of layers 101, 102a, 102b, 102c, 103, 104a, 104b, 104c, 104d, 104e, 104f and a photoresist layer on the hard mask layer, patterning the hard mask layer by exposing and etching the photoresist layer, after removing the photoresist layer, forming the vertical hole in the stack of layers by etching through the stack 120 of layers 101, 102a, 102b, 102c, 103, 104a, 104b, 104c, 104d, 104e, 104f using the hard mask layer, and removing the hard mask layer. By providing one hole 105 through the stack 120 of layers 101, 102a, 102b, 102c, 103, 104a, 104b, 104c, 104d, 104e, 104f, part of the stack 120 of layers is removed, more specifically, part of the alternating conductive and dielectric layers is removed.

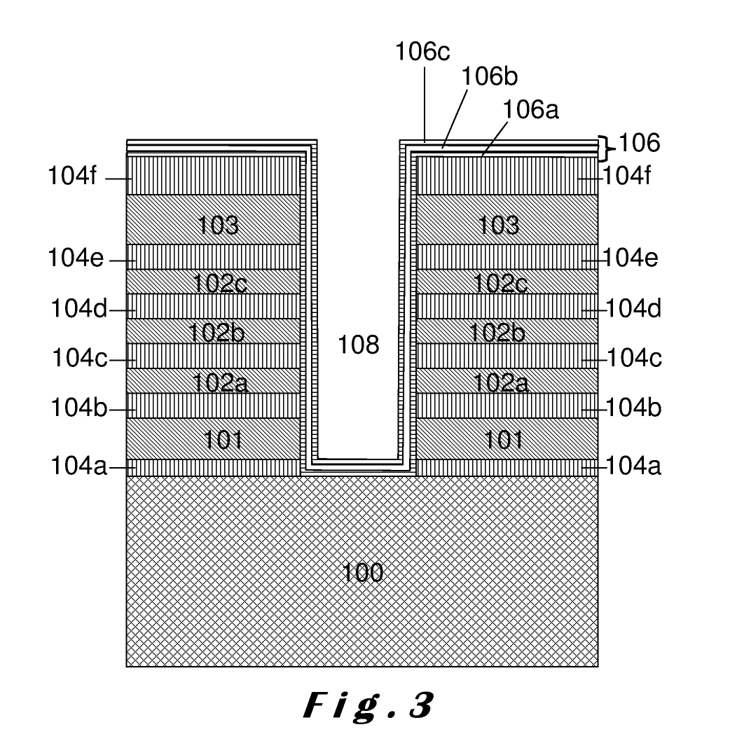

After formation of the hole 105, that is, a vertical hole, a charge storage layer 106 is formed on the sidewall surface 105a and bottom surface 105b of the trench 105 as shown in FIG. 3 as a part of step 204 (FIG. 12). The charge storage layer 106 is conformally formed in the hole 105, that is, along the sidewall 105a and bottom surface 105b of the hole 105. This means the charge storage layer 106 is provided on both the sidewall surface 105a and the bottom surface 105b of the hole 105, thereby leaving a cavity 108 in the hole. The vertical charge storage layer 106 is thus formed at the sidewall surface 105a of the hole 105.

The charge storage layer 106 may comprise one layer or a stack of gate dielectric layers 106a, 106b, 106c. According to one embodiment, the stack of gate dielectric layers comprises a so-called charge trapping layer 106b between two dielectric layers, a so-called charge blocking layer 106a and a so-called charge tunnelling layer 106c.

According to one embodiment, the charge trapping layer 106b may be a dielectric layer with a large density of charge traps (typically 1e19 traps/cm³) sandwiched in between two dielectric layers with a substantially lower density of charge traps when compared to the dielectric layer with a large density of charge traps. As used herein, 1e19 traps/cm³ refers to 10¹⁹ traps/cm³. Preferably, the stack of gate dielectric layers 106 comprises a nitride containing dielectric layer 106b sandwiched in between two oxygen containing dielectric layers 106a, 106c. The stack of gate dielectric layers 106 may, for example, be a stack of a Si₃N₄ layer sandwiched in between two SiO₂ layers. The stack of gate dielectric layers 106 is also often referred to as the ONO or oxygen/nitride/oxygen stack.

In another embodiment, the charge trapping layer 106b may be, for example, be a stack of a poly-Si layers sandwiched in between two SiO₂ layers. The two outer dielectric layers may also comprise a high-k dielectric layer.

The charge storage layer (or stack of gate dielectric layers) 106 is also referred to as the tunnel of the vertical memory device. The charge storage layer 106 will serve as the gate dielectric in between the gates formed by the conductive layers 101, 102a, 102b, 102c, 103 in the stack 120 of layers 101, 102a, 102b, 102c, 103, 104a, 104b, 104c, 104d, 104e, 104f which form control gates and select gates as described above within the vertical channel region which will be formed in the hole 105.

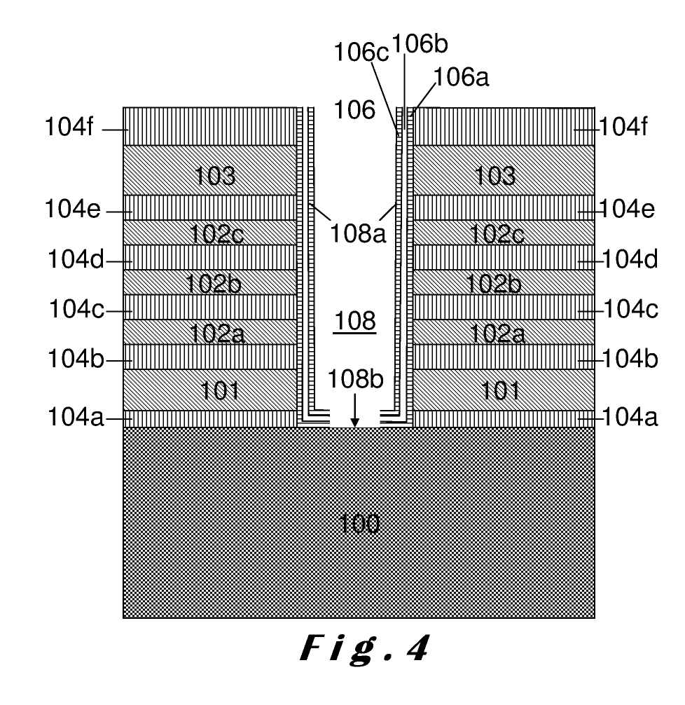

After formation of the charge storage layer 106 or stack of gate dielectric layers, a cavity 108 is provided having sidewalls 108a and a bottom wall 108b. Part of the bottom wall 108b of the cavity 108 may be opened thereby exposing part of the underlying semiconductor material as shown in FIG. 4 also part of step 204 (FIG. 12). The opening of part of the bottom wall 108b of the cavity 108 involves removing part of the charge storage layer 106 which is formed on the bottom wall 108b of the cavity 108b. This is preferably done using an anisotropic etching step.

Alternatively, before removing part of the charge storage layer 106 at the bottom wall 108b of the cavity 108, a capping layer may be provided on the charge storage layer 106 which will protect the charge storage layer 106 at the sidewalls 108a of the trench or cavity 108 during the etching step for opening the bottom of the trench (not shown). By using a capping layer, the interface of the charge storage layer, or in case of a stack of gate dielectric layers, the interface of the upper dielectric layer from the stack of gate dielectric layers remains intact during the etching and/or cleaning step of part of the charge storage layer 106 at the bottom wall 108b of the cavity 108. After etching and/or cleaning the bottom part of the hole, the capping layer may be removed.

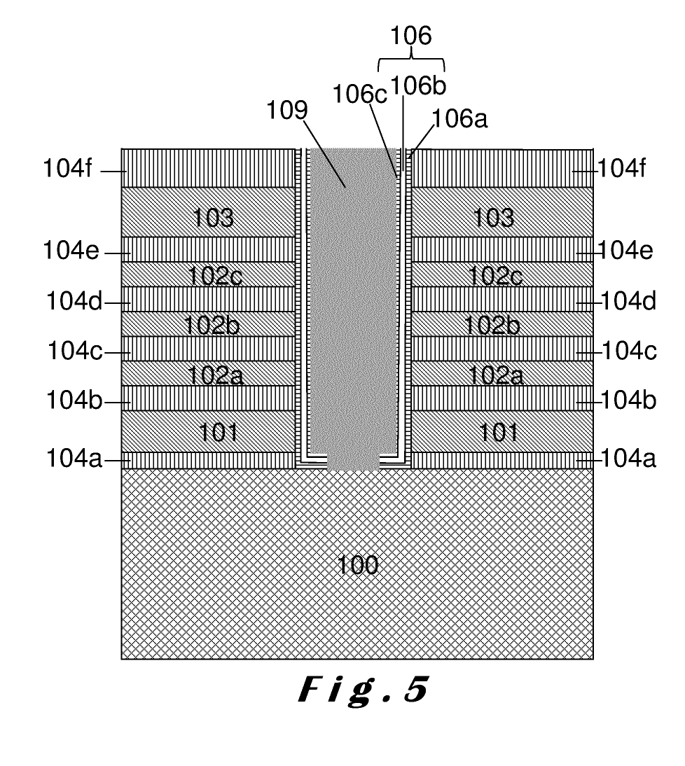

After opening part of the bottom of the trench 108b, the cavity 108 is filled with filling material 109 as shown in FIG. 5. This corresponds to step 205 in FIG. 12. Preferably, the filling material comprises an amorphous semiconducting material, such as, for example, amorphous silicon (a-Si). The filling material may be the same material as the material of the semiconductor substrate 100. The filling material may be a polycrystalline or monocrystalline semiconductor material. Filling of the trench or cavity 108 may be done using chemical vapour deposition (CVD), or more preferably, low pressure chemical vapour deposition (LPCVD). Alternatively, the filling material may be provided into the hole using gas cluster ion beam deposition (GCIB).

After filling the hole, the amorphous semiconducting material 109 used to fill the hole is converted into a channel material. As the material of filling material 109 is preferably an amorphous semiconducting material, and, as the semiconductor substrate material 100 is preferably monocrystalline, the amorphous semiconducting material is thus preferably converted into a monocrystalline semiconducting material. For example, the filling material 109 may consist of amorphous silicon (a-Si) and may be converted into monocrystalline silicon (c-Si). The conversion may be done by using, for example, solid phase epitaxial regrowth (SPER).

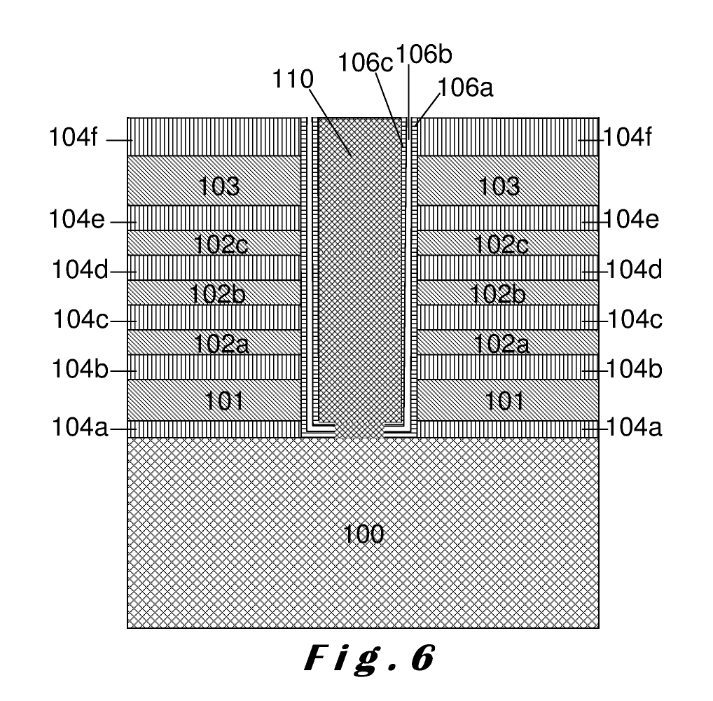

By converting the filling material 109, the vertical channel for the vertical memory device is formed from the converted filling material 110 as shown in FIG. 6. At this point in the integration flow, the vertical semiconductor device already comprises the vertical channel with the charge storage layer along the sidewall surface, the charge storage layer being in contact with the alternating stack of horizontal layers 101, 102a, 102b, 102c, 103, 104a, 104b, 104c, 104d, 104e, 104f.

The filling material may also be polycrystalline, although a monocrystalline channel region 110 has the advantage of having high mobility, a lower concentration of defects compared, for example, to a state-of-the-art polycrystalline channel region, that could lead to non-uniform changes in the device properties, such as, mobility, threshold voltage, etc.

The memory device thus comprises a continuous charge storage layer 106 along the whole length of the stack 120 of conductive and dielectric layers 101, 102a, 102b, 102c, 103, 104a, 104b, 104c, 104d, 104e, 104f, that is, along the length/depth of the vertical channel region.

As described above, it is a disadvantage that stored charge may diffuse along the charge storage layer and more specifically—in case of a stack of gate dielectric layers—the charge trapping layer, and, thereby move away from the region where it can be sensed, that is, the region at the interface between charge storage layer 106 and the conductive layers 102a, 120b, 102c of the stack 120 of layers. Moreover, the stored charge may even diffuse towards a neighbouring cell, thereby interfering with the stored charge at the neighbouring cell so that it can no longer reliably be read out. This effect can be reduced by increasing the spacing between the regions where the charge is stored. This brings a minimum limit to the size and separation in the vertical direction of the different cells in the string. There is, therefore, a need to have the charge storage layer only present at the regions where it is necessary and thus preventing leakage of stored charges, that is, at the interface between the vertical channel and the conductive layers 101, 102a, 102b, 102c, 103, that is, the gate plates of the vertical semiconductor device.

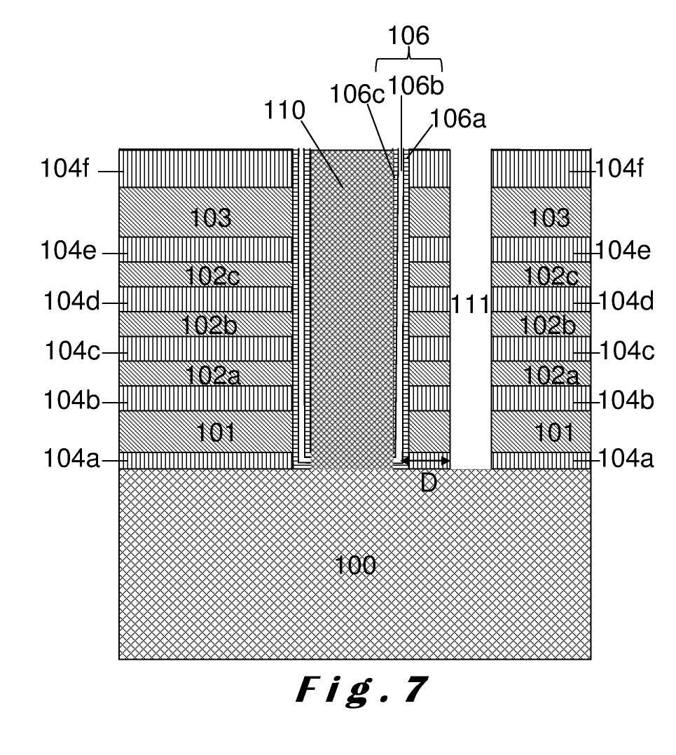

After the formation of the vertical channel region, a vertical dielectric region is formed through the stack 120 of layers 101, 102a, 102b, 102c, 103, 104a, 104b, 104c, 104d, 104e, 104f. Therefore, another opening 111 is provided through the stack 120 of layers 101, 102a, 102b, 102c, 103, 104a, 104b, 104c, 104d, 104e, 104f at a distance D from the channel region 110 of the semiconductor device as shown in FIG. 7. According to one embodiment, the distance D is not 0. The distance D is preferably smaller than 50 nm, more preferably smaller than 30 nm, even more preferably smaller than 20 nm, even more preferably smaller than 10 nm. In other words, a stack of layers (alternating horizontal conductive and dielectric layers) must be present in between each hole and the opening 111. In another embodiment, the opening 111 may be provided in between two adjacent channel regions (not shown).

The openings 111 may be punched through using similar techniques as the hole formation which defines the channel region. The opening 111 may also be a trench.

The formation of the opening 111 may be done using standard process techniques known to a person skilled in the art, such as, for example, a lithography step comprising forming a hard mask layer on the stack of layers and a photoresist layer on the hard mask layer, patterning the hard mask layer by exposing and etching the photoresist layer, after removing the photoresist layer, forming the vertical hole in the stack of layers by etching through the stack of layers using the hard mask layer, and removing the hard mask layer.

According to a preferred embodiment, another opening 111 may be provided thereby exposing part of the underlying semiconductor substrate 100.

By forming another opening 111, part of the conductive layers 101, 102a, 102b, 102c, 103 and the dielectric layers 104a, 104b, 104c, 104d, 104e, 104f of the stack 120 of layers 101, 102a, 102b, 102c, 103, 104a, 104b, 104c, 104d, 104e, 104f is exposed at the sidewall surface of the other opening 111. By forming the other opening 111, part of the underlying semiconductor substrate 100 may be exposed at the bottom of another hole.

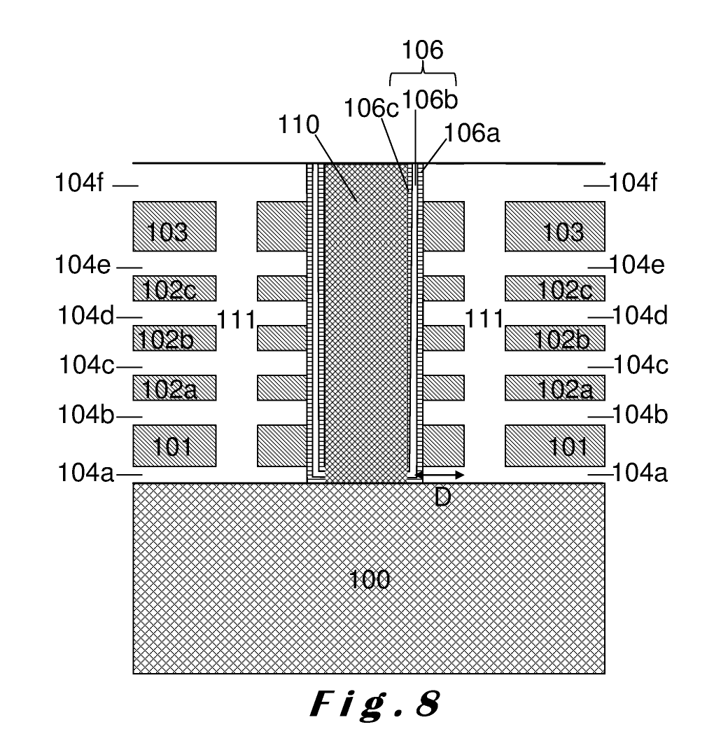

After providing the other opening 111, the exposed dielectric layers 104a, 104b, 104c, 104d, 104e, 104f of the stack 120 of layers 101, 102a, 102b, 102c, 103, 104a, 104b, 104c, 104d, 104e, 104f are removed thereby exposing charge storage layer 106, more specifically, in the case of a stack of gate dielectric layers, the charge blocking layer 106a, which is present along the sidewall surface of the vertical channel region 110 as shown in FIG. 8. The exposed dielectric layers 104a, 104b, 104c, 104d, 104e, 104f of the stack 120 of layers 101, 102a, 102b, 102c, 103, 104a, 104b, 104c, 104d, 104e, 104f may be removed by isotropic etching the dielectric layers. The etching may be dry or wet etching. For example, a hydrogen fluoride (HF) etching may be used for removing the exposed dielectric layers 104a, 104b, 104c, 104d, 104e, 104f. The etching of the layers should not affect the conductive layers 101, 102a, 102b, 102c, 103 of the stack 120 of layers 101, 102a, 102b, 102c, 103, 104a, 104b, 104c, 104d, 104e, 104f. During this etching step, part of the charge storage layer 106 which is in contact with the dielectric layers may also be affected or partially etched. In the case of a stack of gate dielectric layers, the charge blocking layer 106a may also be partially or completely etched during the etching step of the dielectric layers. As it is a goal to remove or alter the charge storage layer, more specifically, in the case of a stack of gate dielectric layers, to remove the charge trapping layer 106b in a next step, it may be advantageous that the etching step of the dielectric layers 104a, 104b, 104c, 104d, 104e, 104f also affects part of the charge storage layer 106.

After removing part of the exposed dielectric layers 104a, 104b, 104c, 104d, 104e, 104f, and possibly part of the charge storage layer 106, the remaining part of the exposed charge storage layer 106 is altered or removed so that charges may no longer move through the charge storage layer at the interface regions between the vertical channel region and the dielectric layers 104a, 104b, 104c, 104d, 104e, 104f and charge storage layer 106, or more specifically, if a gate dielectric stack is used shown by layers 106a, 106b, 106c, through the charge trapping layer 106b.

After removing the exposed dielectric layers 104a, 104b, 104c, 104d, 104e, 104f, the charge storage layer 106 may be further removed or altered.

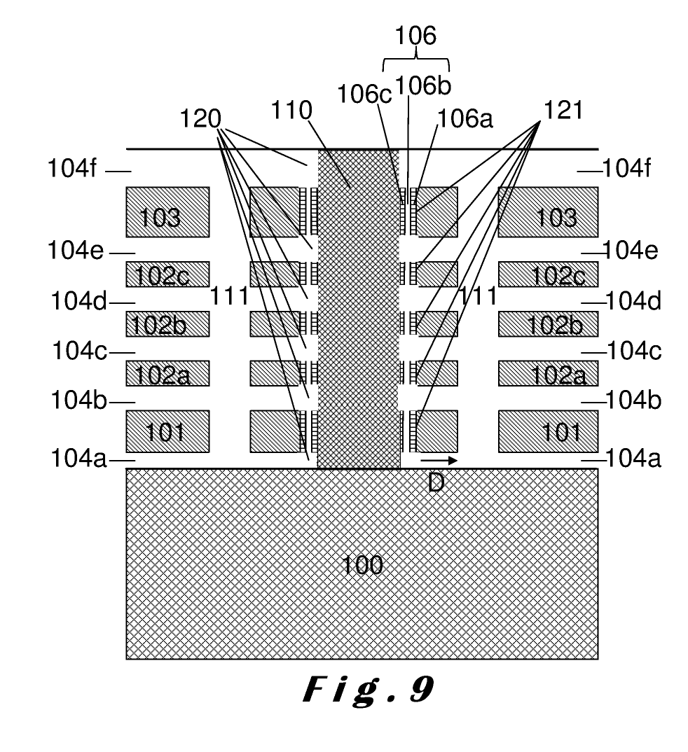

According to one embodiment where the charge storage layer 106 comprises one layer, the charge storage layer 106 is completely removed after removing the exposed dielectric layers 104a, 104b, 104c, 104d, 104e, 104f. This means the charge storage layer 106 remains present at only an interface 121 with the conductive layers 101, 102a, 102b, 102c, 103, but is removed at another interface 120 with the dielectric layers 104a, 104b, 104c, 104d, 104e, 104f as shown in FIG. 9.

According to another embodiment where the charge storage layer 106 comprises a stack of dielectric layers 106a, 106b, 106c, at least the charge trapping layer 106b comprising a large density of traps, that is, 1e19 traps/cm³ or more, such as, for example, a nitride dielectric layer, is removed or altered (not shown).

Removal of the charge storage layer 106 or the charge trapping layer 106b may be done by etching. During this etching step, only the exposed part of charge storage layer 106 may be removed. The charge storage layer parts 121 which are present in between the vertical channel region and the conductive layers 101, 102a, 102b, 102c, 103 must remain present after this etching step as this part of the gate dielectric stack serves as the gate insulating layer between the vertical channel region 110 and the conductive layers 101, 102a, 102b, 102c, 103. If the charge storage layer 106a, 106b, 106c comprises, for example, a nitride-based charge trapping layer 106b, such as, for example, Si₃N₄, a wet etch using phosphoric acid may be used to remove the layer present in between the conductive layers 101, 102a, 102b, 102c, 103.

In the case of a gate dielectric stack of layers 106a, 106b, 106c, at least the charge storage layer 106b should be removed or altered in order to prevent stored charge diffusing even towards an adjacent neighbouring cell, thereby interfering with the stored charge at the neighbouring cell so that it can no longer reliably be read out. In order to have the charge storage layer 106b removed or altered, the outer dielectric layer 106a should also be removed or altered in order to have access to the charge storage layer 106b.

According to another embodiment where a conductive charge storage layer 106b, such as. for example, polysilicon is used, the conductive charge storage layer may be altered to form a new dielectric layer. This may be done by oxidation of the charge storage layer. In another embodiment, where possible, the conductive charge storage layer 106b may also be removed using an etching step. As part of the charge trapping layer 106b, which was present in between the conductive layers 101, 102a, 102b, 102c, 103 and the vertical channel 110, is removed or altered, no charges will diffuse along this layer.

After removing part of the exposed dielectric layers 104a, 104b, 104c, 104d, 104e, 104f, the remaining part of the exposed gate dielectric layers 106a, 106b, 106c may be oxidised. As such, at least the middle dielectric layer 106b is altered so that no charges may diffuse along this layer 106b.

During the removal or oxidation step of the gate dielectric layers, there may be some undercut or under oxidation of the gate dielectric layers which are present in between the vertical channel region 110 and the conductive layers 101, 102a, 102b, 102c, 103. By tuning the etching or oxidation parameters, this undercut or under oxidation can be minimised.

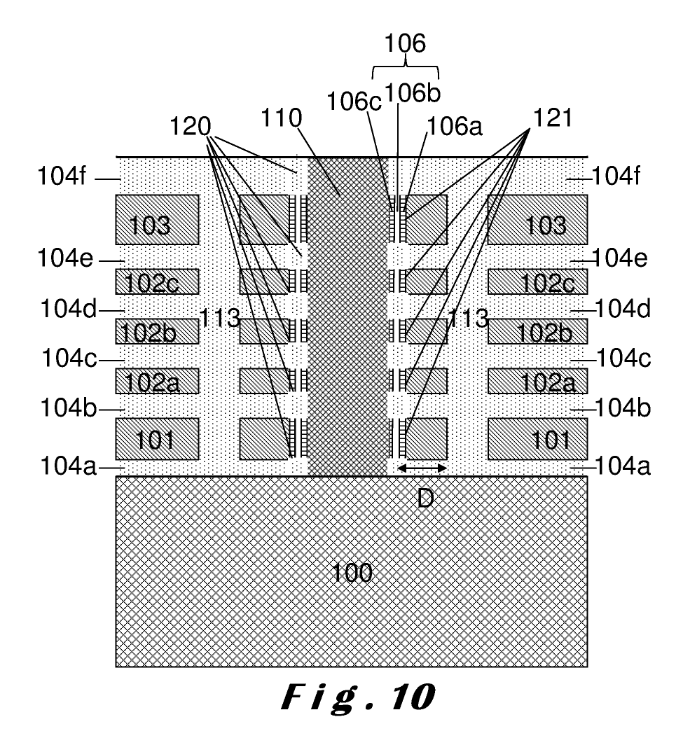

After the step of removing or altering part of the gate dielectric layers, the open areas 111, 120 are refilled. The holes and open areas 111, 120 may be refilled with a dielectric material 113 such as for example SiO₂ or a low-k dielectric material, as shown in FIG. 10. This may be done by using chemical vapour deposition (CVD), or more preferably low pressure chemical vapour deposition (LPCVD). Alternatively, the filling material may be provided for the hole using gas cluster ion beam deposition (GCIB). Alternatively, an air-gap isolation technique may be used for filling the open areas 111, 120.

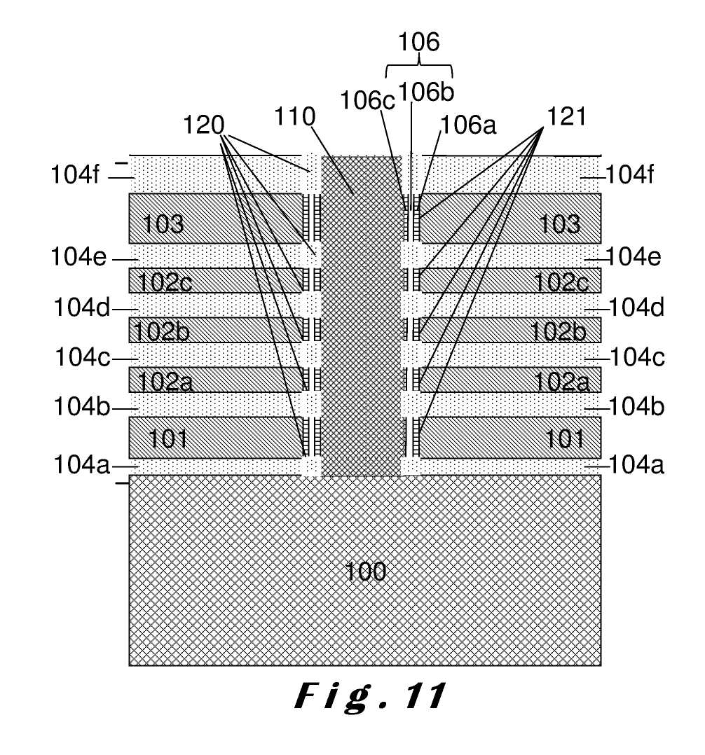

A vertical semiconductor device in accordance with the present invention is shown in FIG. 11. The vertical semiconductor device may be a vertical flash memory device. The channel region 110 of the vertical memory device preferably comprises the same material as the semiconductor substrate 100. More preferably, the semiconductor substrate and channel region may comprise a monocrystalline semiconducting material.

The crystallinity of the semiconducting material of the vertical channel region and of the semiconductor substrate is preferably monocrystalline.

The vertical semiconductor memory device further comprises a stack of alternating horizontal dielectric layers 104a, 104b, 104c, 104d, 104e, 104f and horizontal conductive gate layers 101, 102a, 102b, 102c, 103 on a semiconductor substrate 100. The vertical semiconductor memory device further comprises a vertical channel region 110 extending from the semiconductor substrate 100 through the stack of alternating horizontal layers 101, 102a, 102b, 102c, 103, 104a, 104b, 104c, 104d, 104e, 104f. The vertical semiconductor memory device further comprises a discontinuous or discrete charge storage layer 106, which is present only at the interface 121 between the vertical channel region 110 and the horizontal conductive gate layers 101, 102a, 102b, 102c, 103. The charge storage layer 106 is thus not present in between the vertical channel region 110 and the horizontal dielectric layers 104a, 104b, 104c, 104d, 104e, 104f. The discontinuous charge storage layer 106 is also not present in between the horizontal dielectric layers 104a, 104b, 104c, 104d, 104e, 104f and the horizontal conductive gate layers 101, 102a, 102b, 102c, 103.

The charge storage layer may be a single layer 106 or may be a stack of layers 106a, 106b, 106c as described above.

Whereas in state-of-the-art the charge storage layer is continuously present along the vertical channel region at the interface between the vertical channel region and the stack of horizontal layers, it is an advantage that, for the vertical semiconductor memory device according to the present invention, the charge storage layer is only present at the regions where it is needed, that is, it forms a gate dielectric layer in between the vertical channel region 110 and the horizontal conductive gate layers 101, 102a, 102b, 102c, 103. Due to the fact that the charge storage layer 106 is discontinuous and thus interrupted, the charge storage layer is not present at the interface between the vertical channel region 110 and the horizontal dielectric layers 104a, 104b, 104c, 104d, 104e, 104f. It is an advantage that stored charge cannot move away from the region where it is sensed, that is, the region in between the vertical channel region 110 and the horizontal conductive gate layers 101, 102a, 102b, 102c, 103.

Another aspect of the present invention relates to a method of performing a read and/or write operation on a vertical semiconductor memory device according to at least one embodiment as described herein. The method for performing a read and/or write operation comprises applying specific voltages to the so-called word and bit lines which are defined by the conductive layers 101, 102a, 102b, 102c, 103 and the top surface of the vertical channel region (not shown) respectively.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the invention.

1-16. (canceled)

17. A method for manufacturing a vertical semiconductor device, the method comprising:
providing a semiconductor substrate;
forming a stack of horizontal layers on the semiconductor substrate, wherein (i) the horizontal layers are substantially parallel to a surface of the semiconductor substrate, and (ii) the horizontal layers comprise alternating conductive layers and dielectric layers;
forming a vertical channel region through the stack of horizontal layers, wherein (i) the vertical channel region is substantially perpendicular to a surface of the semiconductor substrate, and (ii) the vertical channel region comprises sidewall surfaces and a bottom surface;
forming a charge storage layer on regions of the sidewall surfaces of the vertical channel region that are in direct contact with conductive layers in the stack of horizontal layers; and
at a distance from the vertical channel region, forming a vertical dielectric region through the stack of horizontal layers.

18. The method of claim 17, wherein forming the vertical dielectric region comprises:
at the distance from the vertical channel region, forming a hole through the stack of horizontal layers;
removing the dielectric layers; and
filling the hole with a dielectric material.

19. The method of claim 17, wherein removing the dielectric layers comprises removing the dielectric layers before forming the charge storage layer.

20. The method of claim 17, further comprising filling the vertical channel region with a semiconductor material.

21. The method of claim 17, further comprising removing portions of the conductive layers.

22. The method of claim 21, wherein removing portions of the conductive layers comprises removing portions of the conductive layers before forming the charge storage layer.

23. The method of claim 17, further comprising removing portions of the charge storage layer that are in direct contact with the dielectric layers.

24. The method of claim 17, wherein forming the charge storage layer on regions of the sidewalls surfaces of the vertical channel region that are in direct contact with conductive layers comprises:
forming the charge storage layer along the sidewall surfaces; and
altering the charge storage layer.

25. The method of claim 24, wherein altering the charge storage layer comprises etching the charge storage layer.

26. The method of claim 24, wherein altering the charge storage layer comprises oxidizing the charge storage layer.

27. The method of claim 17, wherein the charge storage layer comprises a stack of at least a charge tunneling layer, a charge trapping layer, and a charge blocking layer.

28. The method of claim 17, wherein the vertical semiconductor device comprises a vertical semiconductor memory device.

29. A vertical semiconductor device comprising:
a semiconductor substrate;
a stack of horizontal layers formed on the semiconductor substrate, wherein (i) the horizontal layers are substantially parallel to a surface of the semiconductor substrate, and (ii) the horizontal layers comprise alternating conductive layers and dielectric layers;
a vertical channel region through the stack of horizontal layers, wherein (i) the vertical channel region is substantially perpendicular to a surface of the semiconductor substrate, and (ii) the vertical channel region comprises sidewall surfaces and a bottom surface;
a discontinuous charge storage layer present on regions of the sidewall surfaces of the vertical channel region that are in direct contact with conductive layers in the stack of horizontal layers and not present on regions of the sidewall surfaces of the vertical channel region that are in direct contact with dielectric layers in the stack of horizontal layers; and
a vertical dielectric region through the stack of horizontal layers, wherein the vertical dielectric region is at a distance from the vertical channel region.

30. The vertical semiconductor device of claim 29, wherein each dielectric layer is in contact with both the vertical channel region and the vertical dielectric region.

31. The vertical semiconductor device of claim 29, wherein the vertical dielectric region and each of the dielectric layers comprise the same dielectric material.

32. The vertical semiconductor device of claim 29, wherein the charge storage layer comprises a charge trapping layer.

33. The vertical semiconductor device of claim 29, wherein the charge storage layer comprises a stack of a charge blocking layer, a charge trapping layer, and a charge tunneling layer.

34. The vertical semiconductor device of claim 29, wherein the vertical dielectric region comprises air-gap insulation.

35. The vertical semiconductor device of claim 29, wherein:
the vertical channel region comprises a channel of a transistor; and
each of the conductive layers comprises a gate of the transistor.

36. The vertical semiconductor device of claim 35, wherein at least one of the conductive layers comprises a select gate, and at least one of the conductive layers comprises a control gate.
